(19) United States
(12) Patent Application Publication
(10) Pub. No.: US 2011/0305062 A1
(43) Pub. Date: Dec. 15, 2011

(54) MEMORY CELL AND MEMORY DEVICE USING THE SAME

(75) Inventors: Chun Won BYUN, Daejeon (KR); Byeong Hoon Kim, Gyeonggi-do (KR); Sung Min Yoon, Daejeon (KR); Kyoung Ik Cho, Daejeon (KR); Sang Hee Park, Daejeon (KR); Chi Sun Hwang, Daejeon (KR); Min Ki Ryu, Seoul (KR); Shin Hyuk Yang, Gyeonggi-do (KR); Oh Sang Kwon, Daejeon (KR); Eun Suk Park, Daejeon (KR)

(73) Assignee: ELECTRONICS AND TELECOMMUNICATIONS RESEARCH INSTITUTE, Daejeon (KR)

(21) Appl. No.: 12/887,316

(22) Filed: Sep. 21, 2010

(30) Foreign Application Priority Data
Jun. 9, 2010 (KR) 10-2010-0053968

(51) Int. Cl. G11C 11/22

(52) U.S. Cl. 365/145

(57) ABSTRACT

Provided are a memory cell and a memory device using the same, particularly, a nonvolatile non-destructive readable random access memory cell including a ferroelectric transistor as a storage unit and a memory device using the same. The memory cell includes a ferroelectric transistor having a drain to which a reference voltage is applied, a first switch configured to allow a source of the ferroelectric transistor to be connected to a first line in response to a scan signal, and a second switch configured to allow a gate of the ferroelectric transistor to be connected to a second line in response to the scan signal. The memory device enables random access and performs non-destructive read-out (NDRO) operations.

### CROSS-REFERENCE TO RELATED APPLICATION

This application claims priority to and the benefit of Korean Patent Application No. 10-2010-0053968, filed Jun. 9, 2010, the disclosure of which is incorporated herein by reference in its entirety.

### BACKGROUND

1. Field of the Invention

The present invention relates to a memory cell and a memory device using the same and, more particularly, to a nonvolatile non-destructive readable random access memory cell including a ferroelectric transistor as a storage unit and a memory device using the same.

2. Discussion of Related Art

A ferroelectric material may have spontaneous polarization characteristics, and a spontaneous polarization (or remnant polarization) direction of the ferroelectric material may be controlled by the direction of an electric field.

FIG. 1 is a graph showing hysteresis characteristics of a ferroelectric material. Referring to FIG. 1, by applying an electric field V to the ferroelectric material, the ferroelectric material may be polarized (P).

In this case, when the electric field V applied to the ferroelectric material increases to a predetermined value or more in a forward direction, the ferroelectric material may not be polarized but reach a saturated state C in which the ferroelectric material remains polarized.

When the electric field V applied to the ferroelectric material that is in the saturated state C is reduced in a reverse direction, polarization may be gradually reduced (C→D). Even if the electric field V becomes 0, a predetermined value of polarization may remain (see D) in the ferroelectric material. In this case, the polarization remaining in the ferroelectric material may be referred to as remnant polarization.

Thereafter, when the electric field V applied to the ferroelectric material increases in the reverse direction, a polarization state may be moved along a route (D→E→F). In this case, when the electric field applied to the ferroelectric material is increased to a predetermined value or more, the ferroelectric material may be polarized no further and reach a saturated state F in which the ferroelectric material remains in a predetermined polarized state.

Subsequently, when the electric field applied to the ferroelectric material is reduced in the forward direction, the polarization of the ferroelectric material may be changed in a different route from when the electric field V applied to the ferroelectric material is increased in the reverse direction. That is, the polarization of the ferroelectric material may be changed from a route “F→E” to a route “F→A.” In this case, when the electric field becomes 0, the ferroelectric material may have a predetermined remnant polarization A.

Thereafter, when the electric field V applied to the ferroelectric material increases in the forward direction, the polarization state may be changed along a route (A→B→C) and reach the saturated state C.

As a result, after the electric field V applied to the ferroelectric material increases in the forward direction and reaches the saturated state C, when the electric field V is reduced, the polarized state may be changed to a route “C→D→E→F.” Also, after the electric field V applied to the ferroelectric material increases in the reverse direction and reaches the saturated state F, when the electric field V is increased, the polarized state may be changed to a route “F→A→B→C.” This loop may be referred to as a hysteresis loop.

Due to the hysteresis loop, even if the electric field V applied to the ferroelectric material is removed, the ferroelectric material may maintain predetermined values of polarization states A and D due to the remnant polarization.

Conventionally, a ferroelectric random access memory (FeRAM) device has been proposed as a memory device having the above-described ferroelectric material with hysteresis characteristics. The FeRAM device may allow each of the polarized states A and D obtained after an electric field V is removed from the hysteresis loop to correspond to binary data and store data “0” and “1.”

For instance, the FeRAM device may allow a state ‘D’ to correspond to data ‘1’ and allow a state ‘A’ to correspond to data ‘0’ so that the device may store data. In this case, after the electric field V applied to the ferroelectric material increases in the forward direction and reaches the saturated state C, the electric field V may be removed so that the ferroelectric material may have the remnant polarization state D to store the data “1.” Alternatively, after the electric field V applied to the ferroelectric material increases in the reverse direction and reaches the saturated state F, the electric field V may be removed so that the ferroelectric material may have the remnant polarization state A to store the data “0.”

FIG. 2 is a circuit diagram of a conventional memory device using only a ferroelectric transistor.

Referring to FIG. 2, since the conventional memory device employs only the ferroelectric transistor, the memory device may be structurally simple and occupy a relatively small space, thereby improving integration density. However, since interference occurs between adjacent ferroelectric transistors in a read mode, random access may be precluded.

FIG. 3 is a circuit diagram of a conventional memory device including a ferroelectric transistor and an organic transistor. In particular, FIG. 3 shows a case where after data “1” and “0” are stored in a first row, data “0” and “1” are stored in a second row.

Referring to FIG. 3, the conventional memory device includes the ferroelectric transistor and the organic transistor, which are disposed within an array of FeRAM cells. In particular, one memory cell may include an access transistor, a ferroelectric transistor, and an erase transistor and further include three word lines WLA, WLM, and WLE configured to control the access transistor, the ferroelectric transistor, and the erase transistor, respectively, a bit line BL, and a ground line.

Since the memory device having the above-described structure is capable of separately operating ferroelectric transistors disposed in each row, the memory device may enable random access in a read mode.

However, the conventional memory device may preclude exact write operations. When data is to be written in the ferroelectric transistor, a gate drain voltage V_{GD} and a gate source voltage V_{GS} should have the same value to apply a uniform electric field to a ferroelectric material layer. However, in the above-described structure, since a source or drain of the ferroelectric transistor is grounded and clamped at a voltage level, the gate drain voltage V_{GD} may not be equal to the gate source voltage V_{GS}. In this case, the electric field may not be uniformly applied to the ferroelectric material, so that desired data may be highly unlikely to be exactly written in a program mode.

Meanwhile, since the memory device having the above-described structure requires 5 interconnections for each memory cell, each memory cell may require a large area. In other words, there is a technical limit to improving the integration density of the conventional memory device.

### SUMMARY OF THE INVENTION

The present invention is directed to a memory cell and a memory device using the same, which may enable random access, perform exact data write operations in a program mode, and reduce the number of required interconnections to improve integration density.

One aspect of the present invention provides a memory cell including: a ferroelectric transistor having a drain to which a reference voltage is applied; a first switch configured to allow a source of the ferroelectric transistor to be connected to a first line in response to a scan signal; and a second switch configured to allow a gate of the ferroelectric transistor to be connected to a second line in response to the scan signal.

Another aspect of the present invention provides a memory device including: a plurality of memory cells arranged in a first direction and a second direction intersecting the first direction, each memory cell including a ferroelectric transistor, a first switch connected to a source of the ferroelectric transistor, and a second switch connected to a gate of the ferroelectric transistor; a plurality of scan lines connected to gates of the first and second switches of the memory cells arranged in the first direction and configured to apply a scan signal to the gates of the first and second switches of the memory cells arranged in the first direction; a plurality of first lines connected to the first switches of the memory cells arranged in the second direction; a plurality of second lines connected to the second switches of the memory cells arranged in the second direction; and a plurality of reference lines connected to drains of the ferroelectric transistors of the plurality of memory cells and arranged in the second direction.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a graph showing hysteresis characteristics of a ferroelectric material;

FIG. 2 is a circuit diagram of a conventional memory device using only a ferroelectric transistor;

FIG. 3 is a circuit diagram of a conventional memory device including a ferroelectric transistor and an organic transistor;

FIGS. 4 through 6 are diagrams illustrating operations of a ferroelectric transistor according to an exemplary embodiment of the present invention;

FIG. 7 is a circuit diagram of a memory cell according to a first exemplary embodiment of the present invention;

FIG. 8 is a diagram of a cell array of a memory device according to a second exemplary embodiment of the present invention;

FIG. 9 is a diagram of a cell array of a memory device according to a third exemplary embodiment of the present invention;

FIGS. 10A and 10B are diagrams of a cell array of a memory device according to a fourth exemplary embodiment of the present invention;

FIGS. 11 and 12 are circuit diagrams of the cell array of the memory device of FIGS. 10A and 10B; and

FIGS. 13A through 13C are timing diagrams illustrating operations of the memory device of FIGS. 10A and 10B.

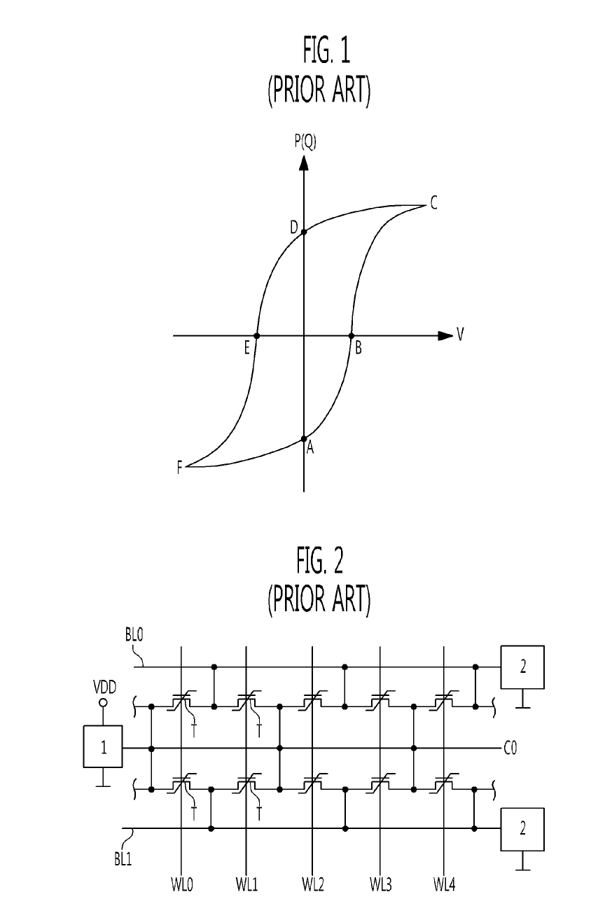

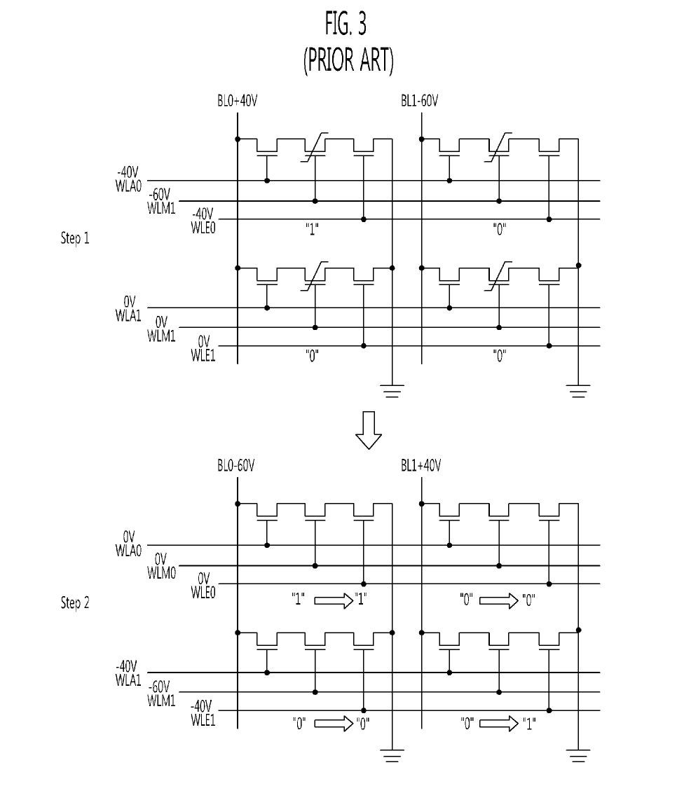

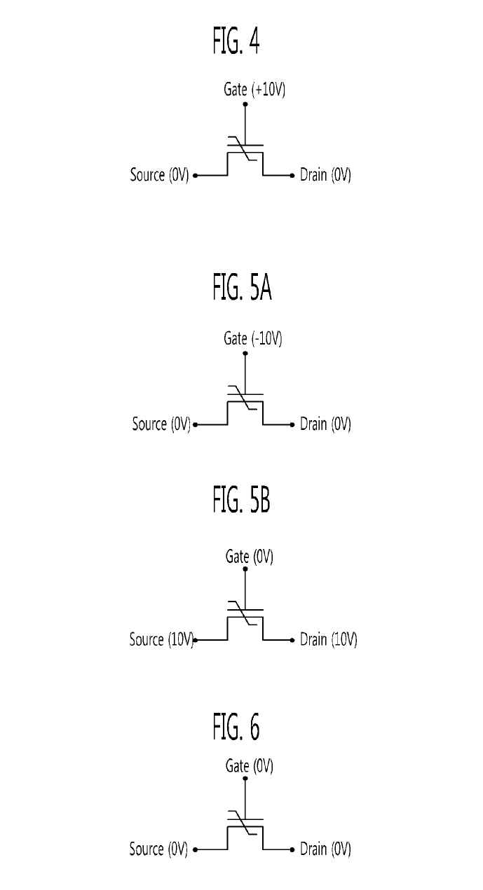

### DETAILED DESCRIPTION OF EMBODIMENTS

The present invention will now be described more fully hereinafter with reference to the accompanying drawings, in which exemplary embodiments of the invention are shown. Descriptions of well-known components and processing techniques are omitted so as not to unnecessarily obscure the embodiments of the present invention.

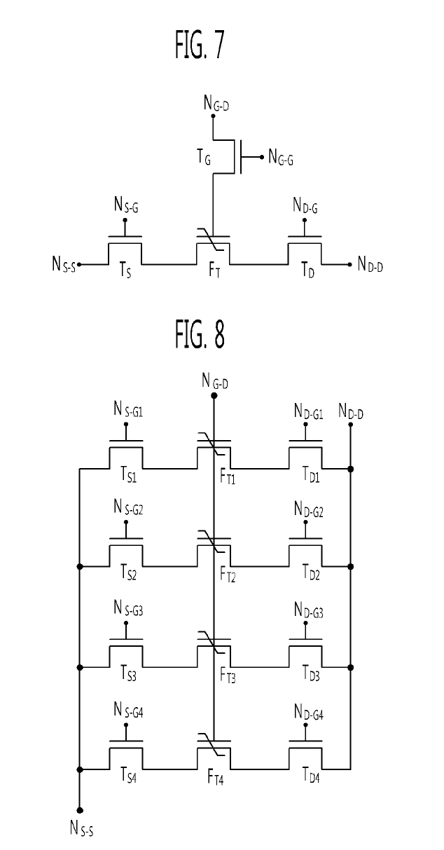

FIGS. 4 through 6 are diagrams illustrating operations of a ferroelectric transistor according to an exemplary embodiment of the present invention. FIGS. 4 through 5B show conditions of a write operation, and FIG. 6 shows conditions in which stored data is retained.

FIG. 4 shows the condition in which data “1” is written in the ferroelectric transistor according to one embodiment of the present invention.

Referring to FIG. 4, a gate drain voltage V_{GD} and a gate source voltage V_{GS} may have predetermined positive values and a source drain voltage V_{SD} may have a value of 0 so that data “1” can be stored in the ferroelectric transistor.

For example, a high-level program voltage may be applied to a gate of the ferroelectric transistor, and a low-level voltage may be applied to a source and a drain of the ferroelectric transistor. FIG. 4 shows a case where a voltage of about 10 V was applied to the gate of the ferroelectric transistor and a voltage of 0 V was applied to the source and drain thereof.

FIGS. 5A and 5B show conditions in which data “0” is written in the ferroelectric transistor according to one embodiment of the present invention.

Referring to FIGS. 5A and 5B, a gate drain voltage V_{GD} and a gate source voltage V_{GS} may have predetermined negative values, and a source drain voltage V_{SD} may have a value of 0 so that data “0” may be stored in the ferroelectric transistor.

For example, a negative program voltage may be applied to the gate of the ferroelectric transistor, and a low-level voltage may be applied to the source and drain thereof. In this case, a negative voltage refers to a voltage having a lower level than the low-level voltage. FIG. 5A shows a case where a voltage of about −10 V was applied to the gate of the ferroelectric transistor and a voltage of 0 V was applied to the source and drain thereof.

As another example, a low-level program voltage may be applied to the gate of the ferroelectric transistor, and a high-level voltage may be applied to the source and drain thereof. FIG. 5B shows a case where a voltage of 0 V was applied to the gate of the ferroelectric transistor and a voltage of about 10 V was applied to the source and drain thereof.

In the above-described write mode, the gate drain voltage V_{GD} and the gate source voltage V_{GS} may have the same value and the source drain voltage V_{SD} may have the value of 0 so that an electric field may be uniformly applied to the ferroelectric material of the ferroelectric transistor. Thus, a polarization state of the ferroelectric material may be clearly controlled so that desired data can be exactly stored.

FIG. 6 shows conditions in which data stored in the ferroelectric transistor is retained.

Referring to FIG. 6, the gate drain voltage V_{GD}, the gate source voltage V_{GS}, and the source drain voltage V_{SD} may have the same value so that an electric field may not be formed in a ferroelectric material of the ferroelectric transistor. Thus, data already stored in the ferroelectric transistor may be retained.

Meanwhile, in order to drive the ferroelectric transistor in the above-described conditions, the respective memory cells of the memory array should be driven separately. That is, voltages of the gate, source, and drain of the ferroelectric transistor should be controlled separately. Hereinafter, the cell array structure of the memory device configured to separately drive the ferroelectric transistors will be described.

FIG. 7 is a circuit diagram of a memory cell according to a first exemplary embodiment of the present invention.

Referring to FIG. 7, a first pass transistor T_{S}, a second pass transistor T_{G}, and a third pass transistor T_{D} may be respectively connected to a source, gate, and drain of a ferroelectric transistor FT to separately control the source, gate, and drain of the ferroelectric transistor FT.

In this case, a signal line “N_{S-G}” may be configured to control the first pass transistor T_{S}, a signal line “N_{G-G}” may be configured to control the second pass transistor T_{G}, and a signal line “N_{D-G}” may be configured to control the third pass transistor T_{D}. Also, a signal line “N_{G-D}” may be a program signal line, a signal line “N_{S-S}” may be an out signal line, and a signal line “N_{D-D}” may be a reference signal line.

However, when the pass transistors T_{S}, T_{G}, and T_{D} are respectively connected to the source, gate, and drain of the ferroelectric transistor FT, the area of each memory cell may be increased, and the signal lines N_{S-G}, N_{G-G}, and N_{D-G} configured to control the pass transistors T_{S}, T_{G}, and T_{D} should be further provided.

FIG. 8 is a diagram of a cell array of a memory device according to a second exemplary embodiment of the present invention.

Referring to FIG. 8, the second embodiment differs from the first embodiment in that the second pass transistor T_{G} connected to the gate of the ferroelectric transistor FT and the signal line N_{G-G} are omitted. Thus, when the cell array is configured without the second pass transistor T_{G}, the area of a memory cell may be reduced more than in the first embodiment.

However, since a program voltage applied through the signal line N_{G-D} is simultaneously applied to the ferroelectric transistors FT1 to FT4 of the corresponding column, when a write operation is to be performed on the first ferroelectric transistor FT1, the write operation may also be performed on the remaining ferroelectric transistors FT2 to FT4 of the corresponding column.

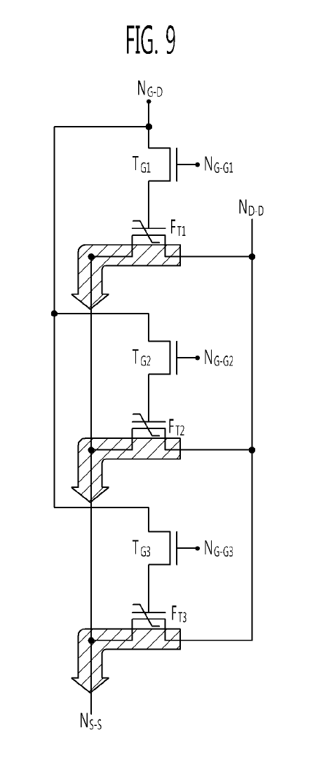

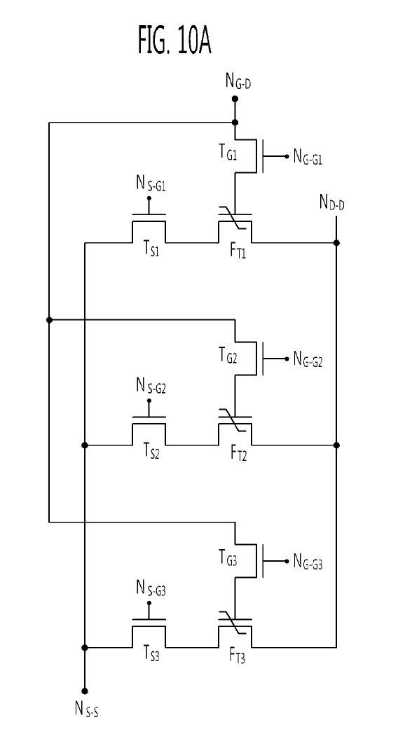

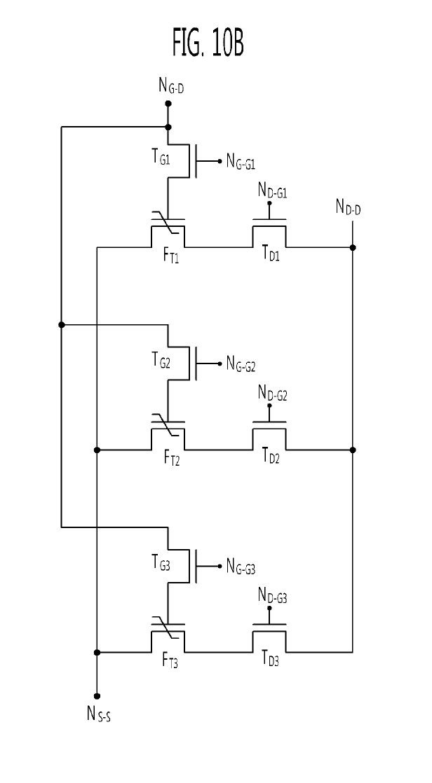

FIG. 9 is a diagram of a cell array of a memory device according to a third exemplary embodiment of the present invention.

Referring to FIG. 9, the present embodiment differs from the first embodiment in that the first and third pass transistors T_{S} and T_{D} connected to the source and drain of the ferroelectric transistor FT and the signal lines N_{S-G} and N_{D-G} are omitted. Thus, when the cell array is configured without the first and third pass transistors T_{S} and T_{D} and the signal lines N_{S-G} and N_{D-G}, the area of each memory cell may be reduced more than in the first embodiment.

However, since the sources of the ferroelectric transistors FT1, FT2, and FT3 arranged in the same column are connected to one another, output data of the sources of the ferroelectric transistors FT1, FT2, and FT3 may be duplicately output through the same out signal line N_{S-S} in a read mode. Thus, even if exact data is stored in the ferroelectric transistors FT1, FT2, and FT3, inexact data may be output in the read mode, thereby lowering reliability.

Furthermore, since source and drain voltages of the ferroelectric transistors FT1, FT2, and FT3 are always varied at the same time, stored data may be destructively read-out (DRO) due to the gate voltages of the floated ferroelectric transistors FT1, FT2, and FT3 and a voltage applied in the read mode.

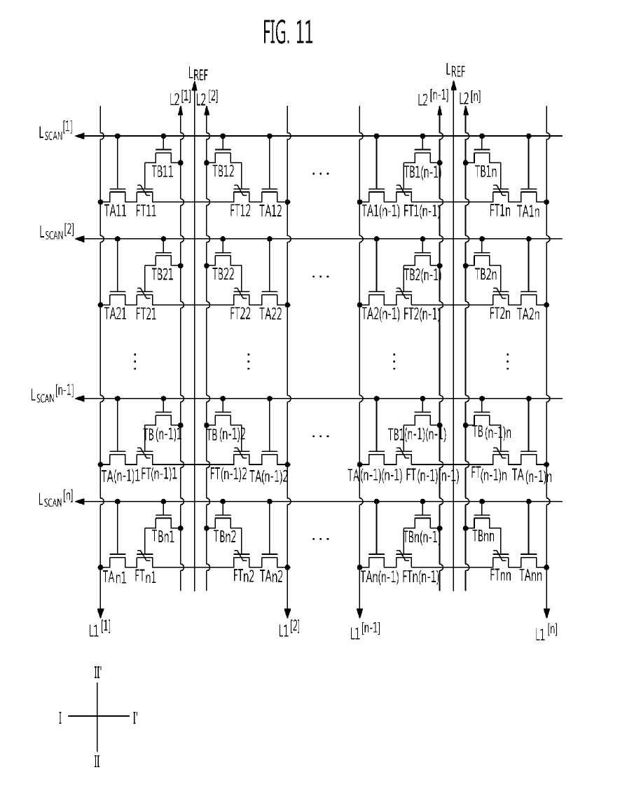

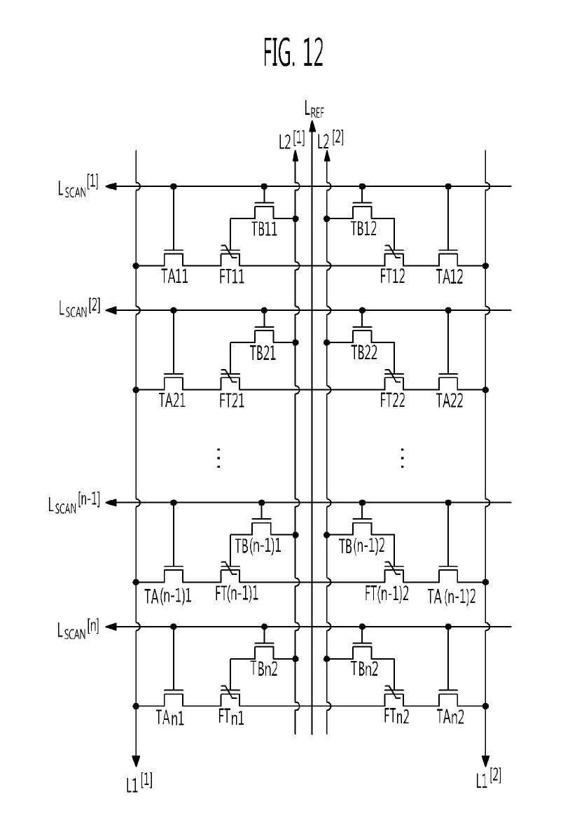

FIGS. 10A and 10B are diagrams of a cell array of a memory device according to a fourth exemplary embodiment of the present invention.

The above-described first through third embodiments describe the memory cell structure and various cell arrays. Thus, it can be seen that the following conditions should be satisfied to separately control a gate, a source, and a drain of a ferroelectric transistor, reduce the area of a memory cell, and enable non-destructive read-out (NDRO) and random access.

First, in order to apply a program signal only to a selected memory cell in a write mode, the memory device should include a second transistor configured to allow connection or disconnection of the gate of the ferroelectric transistor with or from a program signal line.

Second, in order to read only data stored in the selected memory cell and prevent destruction of stored data in a read mode, the memory device should include a first pass transistor configured to allow connection or disconnection of the source of the ferroelectric transistor with or from an out signal line or a third pass transistor configured to allow connection or disconnection of the drain of the ferroelectric transistor with or from a reference signal line.

However, since the source or drain of the ferroelectric transistor may be used as a common electrode, the memory device may include only one of the first and third pass transistors.

FIGS. 10A and 10B show the cell array structure according to the fourth embodiment, which satisfies the above-described conditions. FIG. 10A shows a case where one memory cell includes ferroelectric transistors FT1 to FT3, first pass transistors TS1 to TS3, and second pass transistors TG1 to TG3. Also, FIG. 10B shows a case where one memory cell includes ferroelectric transistors FT1 to FT3, second pass transistors TG1 to TG3, and third pass transistors TD1 to TD3.

In the above-described structure, since one memory cell includes one ferroelectric transistor and two pass transistors, the area of each memory cell may be reduced to further improve integration density.

Also, in the write mode, the gate of the ferroelectric transistor FT1 may be connected to a program signal line N_{G-D} only in the selected memory cell, and the gates of the ferroelectric transistors FT2 to FT3 may be disconnected from the program signal line N_{G-D} in the remaining memory cells so that only the selected memory cell may perform a write operation.

Furthermore, in the read mode, the source of the ferroelectric transistor FT1 may be connected to an out signal line N_{S-S} only in the selected memory cell (in the case shown in FIG. 10A), or the drain of the ferroelectric transistor FT1 may be connected to the reference voltage line N_{D-D} only in the selected memory cell (in the case shown in FIG. 10B) so that the selected memory cell may perform an exact read operation.

FIGS. 11 and 12 are circuit diagrams of a cell array of the memory device of FIGS. 10A and 10B. FIG. 12 is an enlarged view of first and second columns of the cell array of FIG. 11.

Referring to FIGS. 11 and 12, the memory device of the present embodiment may include a plurality of memory cells arranged in a first direction and a second direction intersecting the first direction. Each of the memory cells may include a single ferroelectric transistor FT11 to FTnn and two switches TA11 to TAnn and TB11 to TBnn.

For example, each of the memory cells may include the corresponding one of the ferroelectric memory transistors FT11 to FTnn, the corresponding one of the first switches TA11 to TAnn connected to sources of the ferroelectric memory transistor FT11 to FTnn, and the corresponding one of the second switches TB11 to TBnn connected to gates of the ferroelectric memory transistors FT11 to FTnn.

Furthermore, in order to control the respective memory cells, the memory device may further include scan lines L_{SCAN} configured to control the first and second switches TA11 to TAnn and TB11 to TBnn, a reference line L_{REF}, first lines L1^{[1]} to L1^{[n]}, and second lines L2^{[1]} to L2^{[n]}.

A plurality of scan lines L_{SCAN}^{[1]} to L_{SCAN}^{[n]} may be connected to gates of the first and second switches TA11 to TAnn and TB11 to TBnn of the memory cells arranged in the first direction and apply scan signals V_{SCAN} to the gates of the first and second switches TA11 to TAnn and TB11 to TBnn.

A plurality of first lines L1^{[1]} to L1^{[n]} may be connected to the first switches TA11 to TAnn of the memory cells arranged in the second direction. The first lines L1^{[1]} to L1^{[n]} may be respectively disposed in all columns of the memory cells arranged in the second direction. The first lines L1^{[1]} to L1^{[n]} may apply a source voltage to the ferroelectric transistors FT11 to FTnn in the write mode and output current according to data stored in the ferroelectric transistors FT11 to FTnn in the read mode. After the read mode, the first lines L1^{[1]} to L1^{[n]} may be reset to a low level.

A plurality of second lines L2^{[1]} to L2^{[n]} may be connected to the second switches TB11 to TBnn of the memory cells arranged in the second direction. The second lines L2^{[1]} to L2^{[n]} may be respectively disposed in all columns of the memory cells arranged in the second direction. The second lines L2^{[1]} to L2^{[n]} may apply an appropriate voltage to the gates of the ferroelectric transistors FT11 to FTnn according to the write or read mode of the memory cells.

The reference line L_{REF} may be arranged in the second direction and connected to the drains of the ferroelectric transistors FT11 to FTnn of the memory cells and apply a reference voltage V_{REF} to the drains of the ferroelectric transistors FT11 to FTnn. In this case, adjacent ones of columns of the plurality of memory cells arranged in the second direction may be connected in common to one reference line L_{REF}. That is, as shown in FIGS. 11 and 12, a single reference line L_{REF} may be disposed between first and second columns of the memory cells, and the memory cells in the first and second columns may be connected in common to the reference line L_{REF} disposed therebetween.

In the above-described structure, a reference voltage V_{REF} may be applied to the drains of the ferroelectric transistors FT11 to FTnn. The first switches TAU to TAnn may allow connection of the sources of the ferroelectric transistors FT11 to FTnn with the first lines L1[1] to L1[n] in response to the scan signal V_{SCAN}. Also, the second switches TB11 to TBnn may be connected to the ferroelectric transistors FT11 to FTnn and allow connection of the gates of the ferroelectric transistors FT11 to FTnn with the second lines L2^{[1]} to L2^{[n]} in response to the scan signal V_{SCAN}.

Also, 3.5 interconnections may be required for one memory cell. Specifically, each memory cell may include the scan line V_{SCAN}, the first line L1, and the second line L2 and share a reference line V_{REF} with an adjacent column of memory cells. Thus, the number of interconnections may be reduced compared to the conventional art, thereby improving the integration density of the memory device.

The memory device according to the present embodiment may be driven using the following two methods.

First, the memory device may perform a write operation and a read operation.

In this case, in a write mode, the memory device may store data “1” or “0” in a selected memory cell and retain already stored data in unselected memory cells. In a read mode, the memory device may read data stored in the selected memory cell.

Since the memory device may be driven in two operation modes (i.e., read and write modes) using the above-described methods, the memory device may be driven at high speed. However, since each of a program signal and a scan signal should swing within a large range from a positive voltage to a negative voltage, high power may be consumed during circuit operations.

Second, the memory device may perform a program operation, an erase operation, and a read operation.

In this case, the memory device may perform storage of data “0” in the write mode of the first method as an erase operation, and perform storage of data “1” in the write mode of the first method as a program operation. Of course, the present invention is not limited thereto and may depend on settings. For example, the memory device may perform storage of data “0” as the program operation and perform storage of data “1” as an erase operation.

To begin with, after performing the erase operation on all the memory cells (or after storing data “0”), the memory device may perform the program operation on a selected memory cell (or store data “1” in the selected memory cell). In this case, the memory device may retain already stored data “0” in unselected memory cells. Also, the memory device may read the data stored in the selected memory cell in the read mode.

Although the erase operation may be performed on the entire memory cell, the memory cell may be divided into block units and erased according to circumstances.

In the second method, since both the erase and program operations should be performed to store data, the memory device may be driven at lower speed than in the first method. However, when the erase operation is performed on the condition described with reference to FIG. 5B, since the erase voltage applied to the gate of the ferroelectric transistor does not drop to a negative voltage but swings from 0 to a positive voltage, power consumption may be reduced more than in the first method.

The above-described two methods of driving the memory device may be appropriately selected according to a system to which the present circuit is applied. In the read mode, there may be no difference between the first and second methods so that the memory device may perform the read operation at high speed. However, since there is a difference in write speed between the first and second methods, the first method may be applied to a system that requires high-speed write operations, while the second method may be applied to a system that is independent of operation speed.

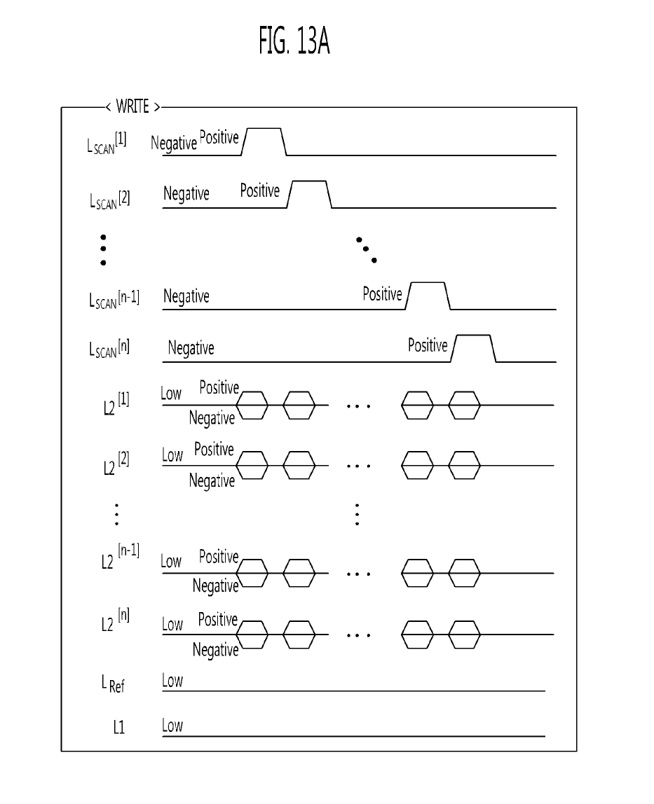

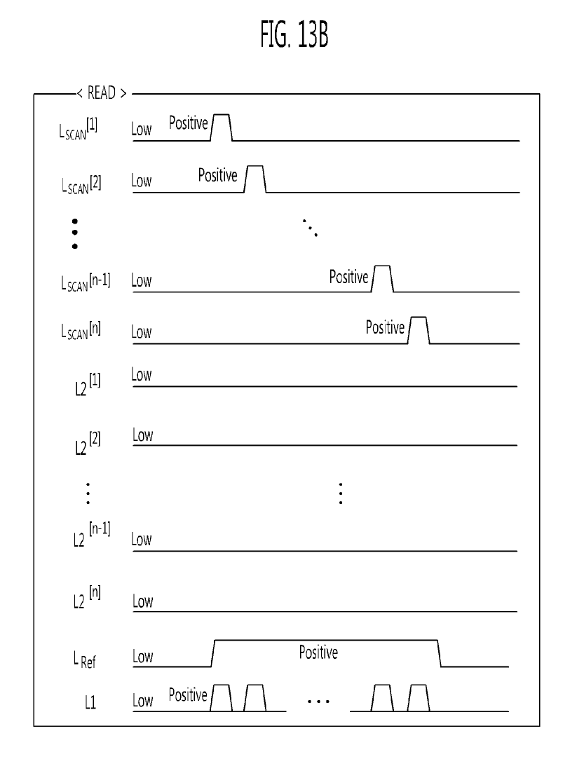

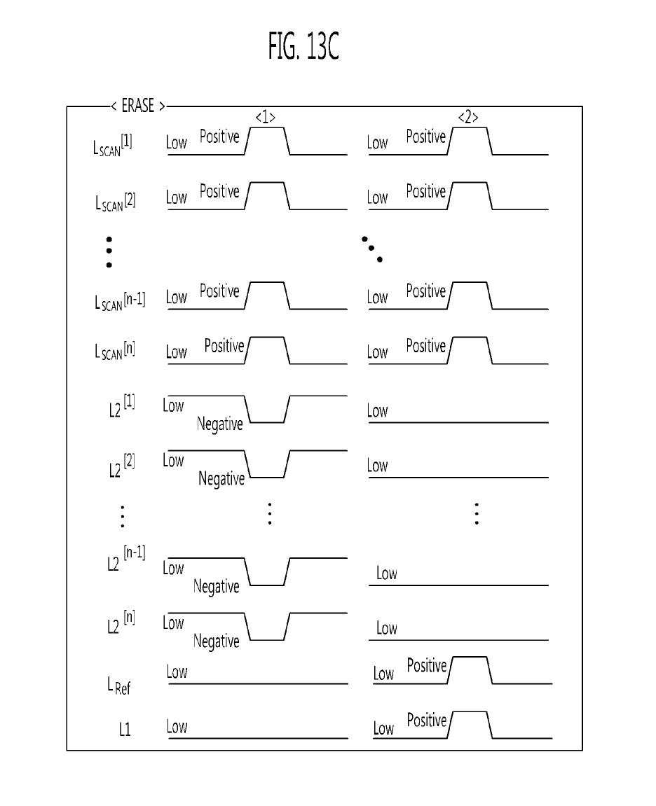

FIGS. 13A through 13C are timing diagrams illustrating operation of the memory device of FIGS. 10A and 10B. Specifically, FIG. 13A shows a write mode, FIG. 13B shows a read mode, and FIG. 13C shows an erase mode.

FIG. 13A is a timing diagram of the write mode of the memory device of FIGS. 10A and 10B.

To begin with, a case where data “1” is stored will now be described.

The scan signal V_{SCAN} may be applied as a pulse signal to the scan line L_{SCAN}. In this case, the scan signal V_{SCAN} applied to the scan line L_{SCAN} connected to a selected memory cell may be enabled to turn on a first switch TA and a second switch TB. Conversely, the scan signal applied to the scan line L_{SCAN} connected to an unselected memory cell may be disabled so that the first and second switches TA and TB may remain turned off.

When the scan signal is enabled, a low-level source voltage may be applied to the first line L1 and then applied to the source of the ferroelectric transistor FT through the first switch TA. Also, a low-level reference voltage may be applied to the reference line L_{REF} and then applied to the drain of the ferroelectric transistor FT. Furthermore, a high-level write voltage may be applied to the second line L2 and then applied to the gate of the ferroelectric transistor FT through the second switch TB of the ferroelectric transistor FT. Thus, data “1” may be stored in the selected memory cell.

Conversely, since the first and second switches TA and TB remain turned off in unselected memory cells, already stored data may be retained.

Next, a case where data “0” is stored will be described.

A scan signal may be applied as a pulse signal to the scan line L_{SCAN}. In this case, the scan signal applied to the scan line L_{SCAN} connected to the selected memory cell may be enabled to turn on the first and second switches TA and TB. Conversely, since the scan signal applied to the scan line L_{SCAN} connected to the unselected memory cells may be disabled, the first and second switches TA and TB may remain turned off.

In this case, in order to store data “0” in the same manner as described with reference to FIG. 5A, when the scan signal is enabled, a negative write voltage may be applied to the second line L2 and then applied to the gate of the ferroelectric transistor FT through the turned-on second switch TB. Also, a negative reference voltage may be applied to the reference line L_{REF} and then applied to the drain of the ferroelectric transistor FT. Furthermore, a low-level write voltage may be applied to the first line L1 and then applied to the source of the ferroelectric transistor FT through the first switch TA. Thus, data “0” may be stored in the selected memory cell.

A case where data “0” is stored in the same manner as described with reference to FIG. 5B will now be described. When the scan signal is enabled, a low-level write voltage may be applied to the second line L2 and then applied to the gate of the ferroelectric transistor FT through the turned-on second switch TB. Also, a high-level reference voltage may be applied to the reference line L_{REF} and then applied to the drain of the ferroelectric transistor FT. Furthermore, a low-level source voltage may be applied to the first line L1 and then applied to the source of the ferroelectric transistor FT through the first switch TA. Thus, data “0” may be stored in the selected memory cell.

Conversely, since the first and second switches TA and TB remain turned off in the unselected memory cells, already stored data may be retained.

In the above-described write mode, the plurality of memory cells may perform the write operation by columns. For example, when the scan signal applied to one row is enabled, scan signals applied to the remaining rows may be disabled. Thereafter, when a scan signal applied to the next row is enabled, scan signals applied to the remaining rows including the previous row may be disabled. Thus, a write voltage may be applied to one row at one time until the write operation is completely performed on all the rows so that desired data can be separately stored in the entire memory cell array.

FIG. 13B is a timing diagram of the read mode of the memory device of FIGS. 10A and 10B.

To begin with, a low-level read voltage may be applied to the second line L2, and a high-level reference voltage may be applied to the reference line L_{REF}. Thereafter, when a scan signal applied to the scan line L_{SCAN} of the selected memory cell is enabled, current may be supplied to the ferroelectric transistor FT, and the flow of current may be expressed as a voltage of the first line L1.

In this case, due to the characteristics of the ferroelectric transistor FT, when data “1” is stored, a larger amount of current may be supplied than when data “0” is stored. Thus, the voltage of the first line L1 may be read to read the data stored in the corresponding memory cell.

Thereafter, after the read mode is finished, the first line L1 may be reset to a ground voltage. When the first line L1 is not reset, since read data of the previous row may be retained in the first line L1, read errors may occur in a read mode of the next row.

FIG. 13C is a timing diagram of the erase mode of the memory device of FIGS. 10A and 10B.

In a case <1> where data “0” is stored in the same manner as described with reference to FIG. 5A to erase data, scan signals applied to the scan lines L_{SCAN}^{[1]} to L_{SCAN}^{[n]} of the entire memory cell array may be enabled. Of course, it is possible that the scan signals applied to the scan lines L_{SCAN}^{[1]} to L_{SCAN}^{[n]} may be sequentially enabled.

In this case, a negative erase voltage may be applied to the second lines L2^{[1]} to L2^{[n]}, a negative low-level reference voltage may be applied to a reference line L_{REF}, and a low-level source voltage may be applied to the second lines L2^{[1]} to L2^{[n]}.

In a case <2> where data “0” is stored in the same manner as described with reference to FIG. 5B, the scan signals applied to the scan lines L_{SCAN}^{[1]} to L_{SCAN}^{[n]} of the entire memory cell array may be enabled. Of course, it is possible that the scan signals applied to the scan lines L_{SCAN}^{[1]} to L_{SCAN}^{[n]} may be sequentially enabled.

In this case, a high-level source voltage may be applied to the first lines L1^{[1]} to L1^{[n]}, a high-level reference voltage may be applied to the reference line L_{REF}, and a low-level source voltage may be applied to the second lines L2^{[1]} to L2^{[n]}. Thus, data “0” may be stored in a plurality of memory cells so as to complete the erase operation.

Although a source and a drain are named as shown in the drawings for brevity, the present invention is not limited thereto. Since the source and drain are relative notions determined by a voltage relationship, it is obvious that the source and drain described in the present specification may be interpreted as a drain and a source, respectively.

According to the present invention as described above, the memory device can enable random access and perform NDRO operations. Also, the memory device may allow a gate drain voltage V_{GA} and a gate source voltage V_{GS} to have the same value in a program mode so that desired data can be exactly written to improve stability of the entire memory system. Furthermore, the number of interconnections required by one memory cell may be reduced, thereby enhancing the integration density of the memory device.

In the drawings and specification, there have been disclosed typical preferred embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A memory cell comprising:
a ferroelectric transistor having a drain to which a reference voltage is applied;
a first switch configured to allow a source of the ferroelectric transistor to be connected to a first line in response to a scan signal; and
a second switch configured to allow a gate of the ferroelectric transistor to be connected to a second line in response to the scan signal.

2. The memory cell of claim 1, further comprising:
a scan line connected to gates of the first and second switches and configured to apply the scan signal to the gates of the first and second switches; and
a reference line connected to the drain of the ferroelectric transistor.

3. The memory cell of claim 1, wherein in a write mode, a low-level source voltage is applied to the first line, a high-level write voltage is applied to the second line, and a low-level reference voltage is applied to the drain of the ferroelectric transistor.

4. The memory cell of claim 1, wherein in an erase mode, a low-level source voltage is applied to the first line, a negative erase voltage is applied to the second line, and a low-level reference voltage is applied to the drain of the ferroelectric transistor.

5. The memory cell of claim 1, wherein in an erase mode, a high-level source voltage is applied to the first line, a low-level erase voltage is applied to the second line, and a high-level reference voltage is applied to the drain of the ferroelectric transistor.

6. The memory cell of claim 1, wherein in a read mode, a low-level read voltage is applied to the second line and a high-level reference voltage is applied to the drain of the ferroelectric transistor so that current output to the first line is read.

7. The memory cell of claim 6, wherein after the read mode, the first line is reset to a low level.

8. A memory device comprising:
a plurality of memory cells arranged in a first direction and a second direction intersecting the first direction, each memory cell including a ferroelectric transistor, a first switch connected to a source of the ferroelectric transistor, and a second switch connected to a gate of the ferroelectric transistor;
a plurality of scan lines connected to gates of the first and second switches of the memory cells arranged in the first direction and configured to apply a scan signal to the gates of the first and second switches of the memory cells arranged in the first direction;
a plurality of first lines connected to the first switches of the memory cells arranged in the second direction;
a plurality of second lines connected to the second switches of the memory cells arranged in the second direction; and
a plurality of reference lines connected to drains of the ferroelectric transistors of the plurality of memory cells and arranged in the second direction.

9. The device of claim 8, wherein the first line is disposed in each column of the plurality of memory cells arranged in the second direction.

10. The device of claim 8, wherein the second line is disposed in each column of the plurality of memory cells arranged in the second direction.

11. The device of claim 8, wherein adjacent ones of columns of the plurality of memory cells arranged in the second direction are connected in common to one reference line.

12. The device of claim 8, wherein in a program or read mode, the plurality of scan lines are sequentially enabled.

13. The device of claim 8, wherein in an erase mode of the plurality of memory cells, the plurality of scan lines are enabled at the same time.
